(19) United States
(12) Patent Application Publication
(10) Pub. No.: US 2013/0082680 A1
(43) Pub. Date: Apr. 4, 2013

(54) ELECTROSTATIC DISCHARGE TESTING APPARATUS

(71) Applicants: TSUNG-PEI WU, Tu-Cheng (TW); XIAO-LIAN HE, Shenzhen City (CN)

(72) Inventors: TSUNG-PEI WU, Tu-Cheng (TW); XIAO-LIAN HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/481,965

(22) Filed: May 29, 2012

(30) Foreign Application Priority Data
Sep. 29, 2011 (CN) 201110292010.3

(51) Int. Cl. G01R 31/00

(52) U.S. Cl. 324/72

(57) ABSTRACT

An electrostatic discharge testing (ESD) apparatus includes a platform, a control unit, an ESD gun, an X rod, a Y rod, and a Z rod respectively parallel to designated XYZ axes of the platform. The Z rod is slidably disposed on the X rod via a first sliding joint, and the Y rod is slidably disposed on the Z rod via a second sliding joint. The ESD gun is disposed on the Y rod. The control unit controls the Z rod to slide along the X rod, and controls the Y rod to slide along the Z rod and along an axis of the Y rod, according to a predetermined testing program. Thus, the ESD gun is moved along a working path to test a product.

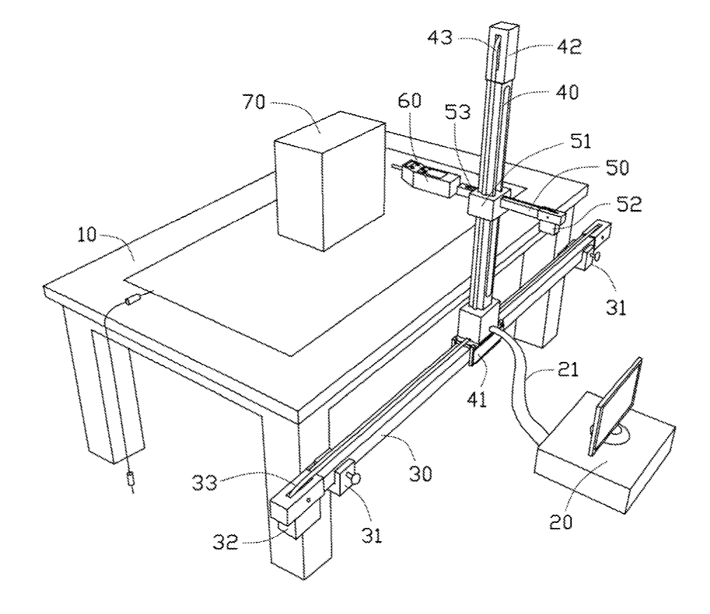

### BACKGROUND

1. Technical Field

The present disclosure relates to equipment used in electrostatic discharge (ESD) testing.

2. Description of Related Art

Electrostatic discharge (ESD) testing workstations generally require a person to hold and move an electrostatic discharge (ESD) gun across products being tested. However, such person's shaking hands may reduce the accuracy of the test result, and the performance of such manual work is inefficient.

Thus, an automatic way to implement an ESD testing process is needed.

### BRIEF DESCRIPTION OF THE DRAWING

The components in the drawing are not necessarily drawn to scale, the emphasis instead being placed upon clearly illustrating the principles of an exemplary electrostatic discharge testing apparatus.

The figure is a perspective view of an electrostatic discharge testing apparatus in accordance with an exemplary embodiment of the present disclosure.

### DETAILED DESCRIPTION

The present disclosure relates to an electrostatic discharge (ESD) testing apparatus capable of automatically moving an electrostatic discharge gun (ESD gun) to test various kinds of semifinished products.

Referring to the drawing, in an exemplary embodiment, the ESD testing apparatus comprises a platform 10, a control unit 20, an X rod 30, a Z rod 40, a Y rod 50, and an ESD gun 60 disposed on one of the three rods 30, 40, 50. In this embodiment, the ESD gun 60 is disposed on the Y rod 50. The ESD testing apparatus is applied to test an object 70, which may be, but is not limited to being, a display panel.

The platform 10 is for supporting the object 70, and includes a metal board covered by an isolation cushion. The metal board is grounded. Furthermore, a position of the platform 10 is defined using an XYZ coordinate system comprising an X axis, a Y axis, and a Z axis (not shown). The X and Y axes are substantially parallel to a top surface of the platform 10, and the Z axis is substantially perpendicular to the top surface of the platform 10. The X rod 30 is parallel to the X axis, the Z rod 40 is parallel to the Z axis, and the Y rod 50 is parallel to the Y axis.

In one embodiment, as shown in the drawing, the X rod 30 is configured at one side of the platform 10, fixed by a Pair of fixed elements 31 of the platform 10, and positioned lower than the top surface of the platform 10. The X rod 30 is provided with a first motor 32 disposed on one end thereof, and a first belt 33. The first motor 32 drives the first belt 33 to move along the X rod 30.

The Z rod 40 is slidably disposed on top of the X rod 30 via a first sliding joint 41. The first sliding joint 41 functions with the first belt 33 to slide the Z rod 40 transverselongitudinally along the X rod 30. The Z rod 40 protrudes up above the top surface of the platform 10, and is provided with a second motor 42 disposed on one end thereof and a second belt 43. The second motor 42 drives the second belt 43 to move along the Z rod 40.

The Y rod 50 is oriented perpendicular to the Z rod 40, and is slidably disposed on the Z rod 40 via a second sliding joint 51. The second sliding joint 51 functions with the second belt 43 to slide the Y rod 50 longitudinally along the Z rod 40. When the Y rod 50 is moved longitudinally along the Z rod 40, the Y rod 50 moves in a limited range, which is entirely above the top surface of the platform 10.

Moreover, the Y rod 50 is configured with a third motor 52 disposed on one end thereof and a third belt 53. The third motor 52 drives the third belt 53 to move along the Y rod 50. The third belt 53 is coupled with the second sliding joint 51, and slides the Y rod 50 along its own longitudinal axis. Therefore the Y rod 50 is capable of sliding relative to the Z rod 40 along two axes. One of the axes is along the Z rod 40 (when the second belt 43 drives the second sliding joint 51), and the other axis is along the Y rod 50 (when the third belt 53 drives the Y rod 50). The ESD gun 60 is disposed on one end of the Y rod 50, and points generally towards an interior space of the platform 10.

The control unit 20 is a computing device having a processor, a memory, and a display. The processor is for executing several programs stored in the memory to perform corresponding functions related to testing. The control unit 20 communicates with the first motor 32, the second motor 42, the third motor 52, and the ESD gun 60 through one or more cables 21. Thereby, the control unit 20 controls the motors 32, 42, 52 and the ESD gun 60 according to a predetermined testing program. More specifically, the control unit 20 controls the first motor 32, the second motor 42, and the third motor 52 to move the ESD gun 60 along a working path, across a surface of the object 70 under test.

Although the present disclosure has been specifically described on the basis of exemplary embodiments, the disclosure is not to be construed as being limited thereto. Various changes or modifications may be made to the embodiments without departing from the scope and spirit of the disclosure.

What is claimed is:

1. An electrostatic discharge (ESD) testing apparatus for automatically moving an electrostatic discharge gun (ESD gun) to test an object, the ESD testing apparatus comprising:
a platform for supporting the object and defining an XYZ coordinate system including an X axis, a Y axis and a Z axis;
an X rod substantially parallel to the X axis and fixed on a side of the platform;
a Z rod substantially parallel to the Z axis and slidably connected with the X rod;
a Y rod substantially parallel to the Y axis and slidably connected with the Z rod, the ESD gun positioned on the Y rod; and
a control unit configured for controlling sliding motion of the X rod, the Y rod and the Z rod and thereby moving the ESD gun along a predetermined working path across the product.

2. The electrostatic discharge testing apparatus of claim 1, further comprising a first motor, a second motor and a third motor; wherein the first motor, the second motor and the third motor are communicatively connected to the control unit and thereby controllable by the control unit; the first motor is configured on the X rod to drive the Z rod to slide along the X rod; the second motor is configured on the Z rod to drive the Y rod to slide along the Z rod; and the third motor is configured on the Y rod to drive the Y rod to slide along a longitudinal axis of the Y rod.

3. The electrostatic discharge testing apparatus of claim 1, wherein the platform comprises a grounded metal board and an isolation cushion, and the metal board is covered by the isolation cushion.
